(19) United States
(12) Patent Application Publication
(10) Pub. No.: US 2014/0077255 A1
(43) Pub. Date: Mar. 20, 2014

(54) SEMICONDUCTOR DEVICE

(71) Applicant: KABUSHIKI KAISHA TOSHIBA, Tokyo (JP)

(72) Inventor: Tatsuo NAIJO, Ishikawa (JP)

(73) Assignee: Kabushiki Kaisha Toshiba, Tokyo (JP)

(21) Appl. No.: 13/787,735

(22) Filed: Mar. 6, 2013

(30) Foreign Application Priority Data
Sep. 18, 2012 (JP) 2012-205048

(51) Int. Cl. H01L 29/739; H01L 23/48

(52) U.S. Cl. CPC H01L 29/7395; H01L 23/48
USPC 257/139; 257/773

(57) ABSTRACT

A semiconductor device has semiconducting layers forming a collector layer, a buffer layer, a drift layer, a base layer, and an emitter layer. The drift layer has alternating regions of n-type and p-type semiconductor material arrayed along a first direction. The drift layer further comprises two stacked layers, each stacked layer with alternating regions of n-type and p-type semiconductor material. Each stacked drift layer portion has a different concentration of n-type and p-type dopants. The stacked drift layer portions also have different thicknesses, such that the interface between the stacked drift layer portions is closer to the buffer layer than base layer. In addition, the regions of n-type and p-type semiconductor material of the drift layer may have the same width in the first direction.

### CROSS-REFERENCE TO RELATED APPLICATION

This application is based upon and claims the benefit of priority from Japanese Patent Application No. 2012-205048, filed Sep. 18, 2012; the entire contents of which are incorporated herein by reference.

### FIELD

Embodiments described herein relate to a semiconductor device.

### BACKGROUND

To meet the demand of smaller size and higher performance power supply equipment in the field of power electronics, there have been efforts to improve the performance of power electronic semiconductor devices, such as an Insulated Gate Bipolar Transistor (IGBT), so as to realize high voltage ratings, higher currents, as well as lower losses, higher resistance to breakdown, and higher speed of operation.

However, for the IGBT elements, when electron holes (holes) are injected from the collector side into the element due to the bipolar operation, a negative resistance is generated inside the element, and the breakdown tolerance of the element may become degraded.

### DESCRIPTION OF THE DRAWINGS

FIGS. 1A and 1B are schematic diagrams illustrating the semiconductor device according to a first embodiment. FIG. 1A is a schematic cross-sectional view. FIG. 1B is a schematic plane view.

FIGS. 2A and 2B are diagrams illustrating the electric field in the drift layer of the semiconductor device according to a first reference example. FIG. 2A is a schematic cross-sectional view of the semiconductor device, and FIG. 2B is a diagram illustrating the relationship between the position in the drift layer and the electric field.

FIGS. 3A and 3B are diagrams illustrating the electric field in the drift layer of the semiconductor device according to a second reference example. FIG. 3A is a schematic cross-sectional view of the semiconductor device. FIG. 3B is a diagram illustrating the relationship between the position in the drift layer and the electric field.

FIG. 4 is a diagram illustrating the voltage versus current characteristics of the semiconductor device according to the first and second reference examples.

FIGS. 5A and 5B are diagrams illustrating the electric field in a super-junction structure of a semiconductor device according to a first embodiment. FIG. 5A is a schematic cross-sectional view of the semiconductor device. FIG. 5B is a diagram illustrating the relationship between the position in the super-junction structure and the electric field.

FIGS. 6A and 6B are diagrams illustrating the electric field in a super-junction structure of a semiconductor device according to a third reference example. FIG. 6A is a schematic cross-sectional view of the semiconductor device. FIG. 6B is a diagram illustrating the relationship between the position in the super-junction structure and the electric field.

FIGS. 7A and 7B are diagrams illustrating the electric field in the super-junction structure of the semiconductor device according to the first embodiment. FIG. 7A is a schematic cross-sectional view of the semiconductor device. FIG. 7B is a diagram illustrating the relationship between the position in the super-junction structure and the electric field.

FIG. 8 is a diagram illustrating the voltage versus current characteristics of the semiconductor device according to the first embodiment and the second reference example.

FIGS. 9A and 9B are schematic diagrams of a semiconductor device according to a second embodiment. FIG. 9A is a schematic cross-sectional view. FIG. 9B is a schematic plane view.

### DETAILED DESCRIPTION

One purpose of the present disclosure is to provide a semiconductor device that can improve the breakdown tolerance of IGBT elements.

In general, an embodiment will be explained with reference to the figures. In the following explanation, the same reference numerals are adopted throughout, and, once an element is explained, it will not be explained again.

The semiconductor device in an embodiment of the present disclosure has: a first semiconductor layer of a first electroconductive (conductivity) type, a second semiconductor layer of a second electroconductive type, the second semiconductor layer disposed on the first semiconductor layer, a third semiconductor layer disposed on the second semiconductor layer. The third semiconductor layer has first semiconductor regions of the first electroconductive type and second semiconductor regions of the second electroconductive (conductivity) type. The first semiconductor regions and the second semiconductor regions alternate with each other in a first direction. The first direction is perpendicular to the laminating (stacking) direction (e.g., the direction perpendicular to the device substrate) of the first semiconductor layer and the second semiconductor layer. A fourth semiconductor layer disposed on the third semiconductor layer has a third semiconductor regions of the first electroconductive type and fourth semiconductor regions of the second electroconductive type. The third semiconductor regions and the fourth semiconductor regions are arranged alternately in the first direction. A fifth semiconductor layer of the first electroconductive type is disposed on the fourth semiconductor layer. A sixth semiconductor layer of a second electroconductive type is disposed on the fifth semiconductor layer. A first electrode is disposed on an insulating film disposed on the sixth semiconductor layer, the fifth semiconductor layer, and the fourth semiconductor regions. A second electrode is connected to the sixth semiconductor layer. And a third electrode is connected to the first semiconductor layer.

The concentration of the impurity element (first dopant) contained in the second semiconductor regions is higher than the concentration of the impurity element (second dopant) contained in the first semiconductor regions; the concentration of the impurity element (first dopant) contained in the third semiconductor regions is higher than the concentration of the impurity element (second dopant) contained in the fourth semiconductor regions, thus the third semiconductor layer and the fourth semiconductor layer have different relative concentrations of first and second dopants; and a first length between an upper end of the second semiconductor layer and the interface between the third semiconductor layer and the fourth semiconductor layer is less than a second length between the interface and the lower surface of the fifth semiconductor layer.

### First Embodiment

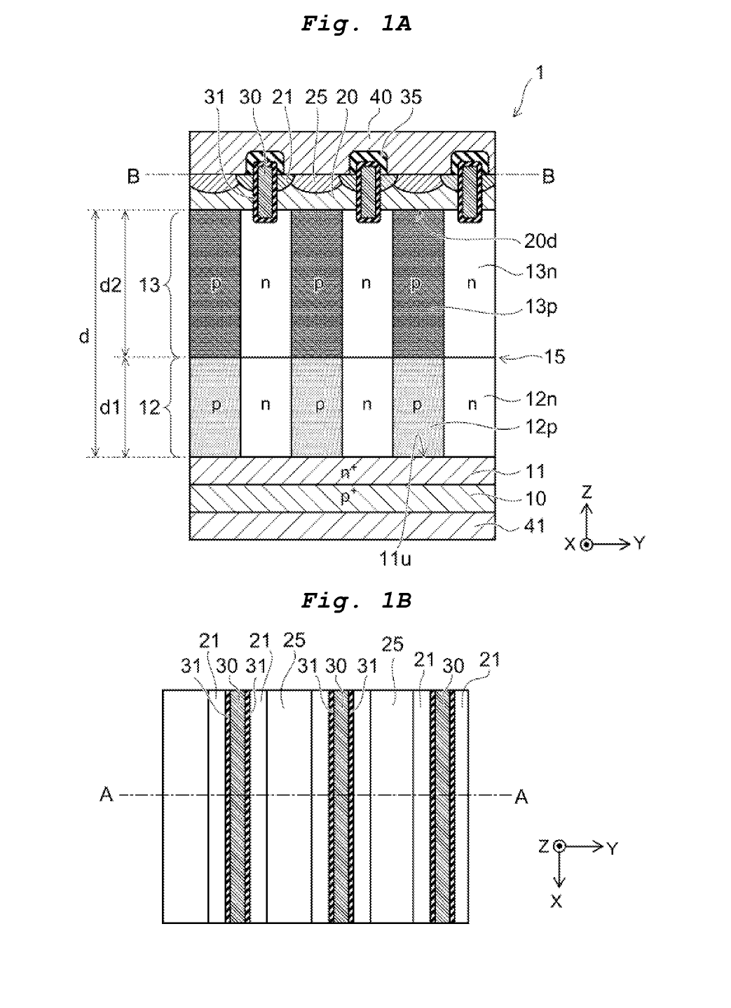

FIGS. 1A and 1B include schematic diagrams illustrating the semiconductor device according to the first embodiment.

FIG. 1A is a schematic cross-sectional view. FIG. 1B is a schematic plane view.

FIG. 1A is a cross-sectional view taken across A-A of FIG. 1B.

FIG. 1B is a cross-sectional view taken across B-B of FIG. 1A.

The semiconductor device 1 according to the first embodiment is an IGBT (Insulated Gate Bipolar Transistor) element with an upper/lower electrode structure. In the following, p type dopants (at various concentration levels) will generally be referred to as the first electroconductive type and n type dopants (at various concentration levels will generally be referred to as the second electroconductive type, but in some embodiments the first and second electroconductive types could be, respectively, n type and p type materials instead.

In the semiconductor device 1, on the p+ type (first conductivity type) collector layer 10 (first semiconductor layer), an n+ type (second conductivity type) buffer layer 11 (second semiconductor layer) is arranged. On the buffer layer 11, a semiconductor layer 12 (third semiconductor layer) is arranged. On the semiconductor layer 12, a semiconductor layer 13 (fourth semiconductor layer) is arranged.

The semiconductor layer 12 has a super-junction structure. On the semiconductor layer 12, the p type (first electroconductive type) semiconductor layer regions 12p (first semiconductor regions) and the n type (second electroconductive type) semiconductor layer regions 12n (second semiconductor regions) are arranged alternately in the first direction (Y-direction) perpendicular to the laminating direction (Z-direction) of the collector layer 10 and the buffer layer 11. The shape of the semiconductor layer regions 12p and the semiconductor layer regions 12n are a pillar shape on the cross-section shown as an example in FIG. 1A. The semiconductor layer regions 12p and the semiconductor layer regions 12n extend in X-direction. The semiconductor layer regions 12p and semiconductor layer regions 12n are jointed to the buffer layer 11. The semiconductor layer regions 12p and the semiconductor layer regions 12n have the same width in X-direction.

The semiconductor layer 13 has a super-junction structure. In the semiconductor layer 13, p type semiconductor layer regions 13p (third semiconductor regions) and n type semiconductor layer regions 13n (fourth semiconductor regions) are arranged alternately in the first direction (Y-direction) perpendicular to the laminating direction (Z-direction). The semiconductor layer regions 12p are connected to the semiconductor layer regions 13p. The semiconductor layer regions 12n are connected to the semiconductor layer regions 13n. The shape of the semiconductor layer regions 13p and the semiconductor layer regions 13n are a pillar shape on the cross-section shown as an example in FIG. 1A. The semiconductor layer regions 13p and the semiconductor layer regions 13n extend in X-direction. The semiconductor layer regions 13p and the semiconductor layer regions 13n have the same width in the X-direction.

For the semiconductor device 1, a p type base layer 20 (fifth semiconductor layer) is arranged on the semiconductor layer regions 13p and the semiconductor layer regions 13n. On the base layer 20, an n type emitter layer 21 (sixth semiconductor layer) is arranged. In addition, on the base layer 20, a p+ type semiconductor layer 25 jointed to (in contact with) the emitter layer 21 is arranged. The p+ semiconductor layer 25 may also be called a hole-extracted layer.

In the semiconductor device 1, the gate electrode 30 (first electrode) is jointed via the gate insulating film 31 to the emitter layer 21, the base layer 20, and the semiconductor layer regions 13n, respectively. On the cross-section shown in FIG. 1A, the gate electrode 30 extends in the Z-direction. That is, the semiconductor device 1 has a trench gate structure gate electrode 30. The gate electrode 30 also extends in X-direction in addition to the Z-direction. In addition to the trench gate structure, the gate electrode may have a planar structure.

In addition, in the semiconductor device 1, the emitter electrode 40 is connected to the emitter layer 21 and the p+ type semiconductor layer 25. An interlayer insulating film 35 is arranged between the emitter electrode 40 and the gate insulating film 31. The collector electrode 41 (third electrode) is connected to the collector layer 10.

Silicon (Si), for example, may be the principal ingredient of the collector layer 10, the buffer layer 11, the semiconductor layer 12, the semiconductor layer 13, the base layer 20, the emitter layer 21, and the p+ type semiconductor layer 25. The semiconductor layers 12, 13 may be epitaxial layers or ion implanting layers. The principal ingredient of the gate electrode 30 is polysilicon. An impurity element (dopant) is doped in to the polysilicon. The gate electrode 30 becomes an electroconductive layer.

The p+ type and p type semiconductor layers are semiconductor layers containing boron (B) or other similar impurity elements. The n+ type and n type semiconductor layers are semiconductor layers containing, e.g., phosphorus (P), arsenic (As), or other impurity elements. The principal ingredient of the gate insulating film 31 may be, for example, a silicon oxide (SiOₓ), a silicon nitride (SiₓN_{y}), etc. The principal ingredient of the interlayer insulating film 35 may be, for example, a silicon oxide (SiOₓ). The principal ingredients of the collector electrode 41 and emitter electrode 40 may be, for example, at least one type of metals of aluminum (Al), copper (Cu), tungsten (W), titanium (Ti), nickel (Ni), platinum (Pt), gold (Au), etc.

For the semiconductor layer 12, the concentration of the impurity element (dopant) contained in the semiconductor layer regions 12n is higher than the concentration of the impurity element contained in the semiconductor layer regions 12p. The semiconductor layer 12 is the so-called n-rich semiconductor layer. For the semiconductor layer 13, the concentration of the impurity element (dopant) contained in the semiconductor layer regions 13p is higher than the concentration of the impurity element contained in the semiconductor layer regions 13n. The semiconductor layer 13 is the so-called p-rich semiconductor layer.

In this embodiment, the length d1 (first length) between the upper surface 11u of the buffer layer 11 and the interface 15 between the semiconductor layer 12 and the semiconductor layer 13 is less than the length d2 (second length) between the interface 15 and the lower end 20d of the base layer 20. That is, the interface 15 between the semiconductor layer 12 and the semiconductor layer 13 is located closer to the buffer layer 11 than at the position which would be half of the length d as a sum of d1 and d2. In other words, when the semiconductor layer 12 and the semiconductor layer 13 are taken as the drift layer of the semiconductor device 1, the interface 15 is located at a position less than half the total drift layer thickness (d1+d2) from buffer layer 11.

In the above, an n channel type transistor is presented as an example of the semiconductor device 1. However, the present embodiment also includes the p channel type transistor that has the n type and p type swapped with respect to the transistor.

Before going to into explanation of the operation of the semiconductor device 1, first, explanation will be made on the operation of the semiconductor devices according to reference examples.

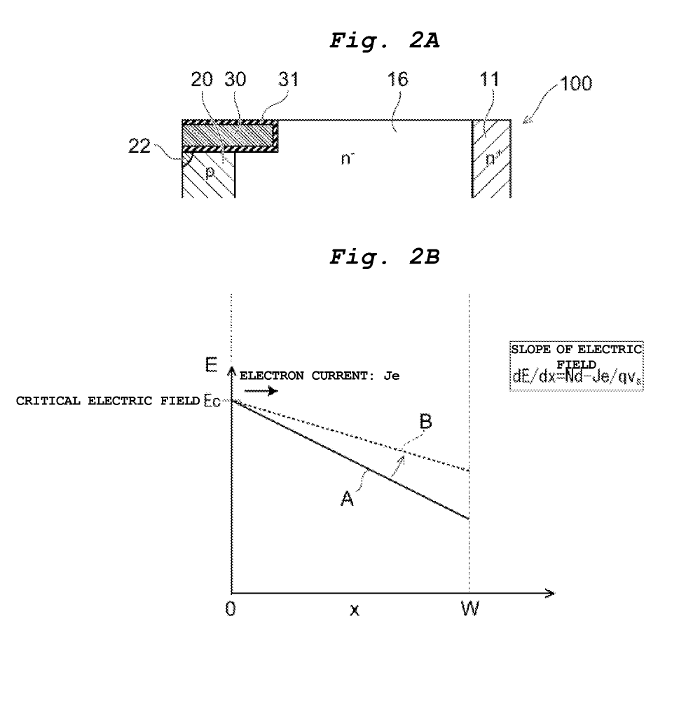

FIGS. 2A and 2B include diagrams illustrating the electric field in the drift layer of the semiconductor device according to Reference Example 1. FIG. 2A is a schematic cross-sectional view of the semiconductor device, and FIG. 2B is a diagram illustrating the relationship between the position in the drift layer of the semiconductor device and the electric field.

In FIG. 2B, the abscissa represents the distance from the boundary between the base layer 20 and the drift layer 16 to the boundary between the drift layer 16 and the buffer layer 11. The boundary between the base layer 20 and the drift layer 16 corresponds to the position of “0” shown in FIG. 2B. The boundary between the drift layer 16 and the buffer layer 11 corresponds to the position of “W” shown in FIG. 2B. In FIG. 2B, the ordinate represents the electric field.

The line of “A” is a line representing the relationship between the position in the drift layer right after an avalanche breakdown and the electric field after application of the voltage between the source and the drain. In addition, the line of “B” is a line representing the relationship between the position in the drift layer after a prescribed time since the avalanche and the electric field. Here, a positive potential is applied on the drain side (the side of the buffer layer 11), and a negative potential or a ground potential is applied on the source side.

For each line, the value obtained by integrating the electric field Ec from position 0 to position W (the area of the portion defined by the vertical lines at position 0 and position W and line A or line B) corresponds to the voltage between position 0 and position W. Ec represents the critical electric field where an avalanche takes place.

The semiconductor device 100 shown in FIG. 2A is a MOSFET (Metal Oxide Semiconductor Field Effect Transistor) element with an upper/lower electrode structure. The semiconductor device 100 has: n+ type buffer layer 11, n− type drift layer 16 jointed to the buffer layer 11, p type base layer 20 jointed to the drift layer 16, and n+ type source layer 22 jointed to the base layer 20. In addition, in the semiconductor device 100, the gate electrode 30 is jointed via the gate insulating film 31 to the source layer 22, the base layer 20 and the drift layer 16, respectively.

As shown in FIG. 2B, in the semiconductor device 100, line B is on the upper side of line A. Consequently, after generation of an avalanche, as the avalanche current increases, the voltage applied in the drift layer 16 increases. That is, in the drift layer 16 of the semiconductor device 100, in the avalanche, a normal positive resistance characteristic feature is displayed with an increase in the voltage as the avalanche current increases.

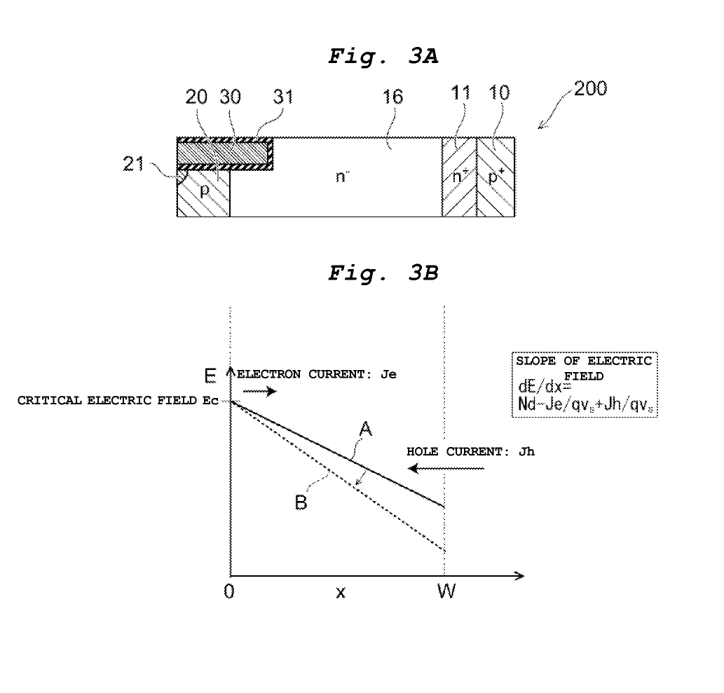

FIGS. 3A and 3B include diagrams illustrating the electric field in the drift layer of the semiconductor device according to Reference Example 2. FIG. 3A is a schematic cross-sectional view of the semiconductor device. FIG. 3B is a diagram illustrating the relationship between the position in the drift layer of the semiconductor device and the electric field.

The format of FIG. 3B is the same as that of FIG. 2B. On the collector side of the semiconductor device 200, a positive potential is applied, and, on the emitter side, a negative or a ground potential is applied.

The semiconductor device 200 shown in FIG. 3A is an IGBT element with an upper/lower electrode structure. Here, the super-junction structure is not set in the semiconductor device 200. The semiconductor device 200 has: a p+ type collector layer 10, a buffer layer 11 jointed to the collector layer 10, a drift layer 16 jointed to the buffer layer 11, a base layer 20 jointed to the drift layer 16, and the emitter layer 21 jointed to the base layer 20. In addition, the semiconductor device 200 has a gate electrode 30.

As shown in FIG. 3B, in the semiconductor device 200, line B is on the lower side of line A. Consequently, after generation of an avalanche, as the avalanche current increases, the voltage applied in the drift layer 16 decreases. That is, in the drift layer 16 of the semiconductor device 200, when an avalanche takes place, as the avalanche current increases, the voltage decreases, that is, a negative resistance is generated.

In the following, the reason for generation of a negative resistance in the IGBT element will be explained.

The IGBT element contains a MOS structure on the surface side where electrons are injected, and a p+ type collector layer 10 on the inner surface side where electron holes (holes) are injected. As a result, the IGBT element carries out the bipolar operation.

When an avalanche breakdown takes place at the interface between the base layer 20 and the drift layer 16, an electron current is generated in the drift layer 16, and, corresponding with generation of electrons, holes are injected from the collector layer 10. Under the influence of the holes, the electric field distribution of the drift layer 16 becomes steep. That is, as shown in FIG. 3B, transition is made from line A to line B. Consequently, in the IGBT element, generation of the negative resistance at an avalanche is easier than the MOSFET (or diode).

Usually, in an element that displays a negative resistance, as the voltage decreases while the current increases, localized current concentration may occur/form inside the element. As a result, the overall tolerance to breakdown of the element decreases.

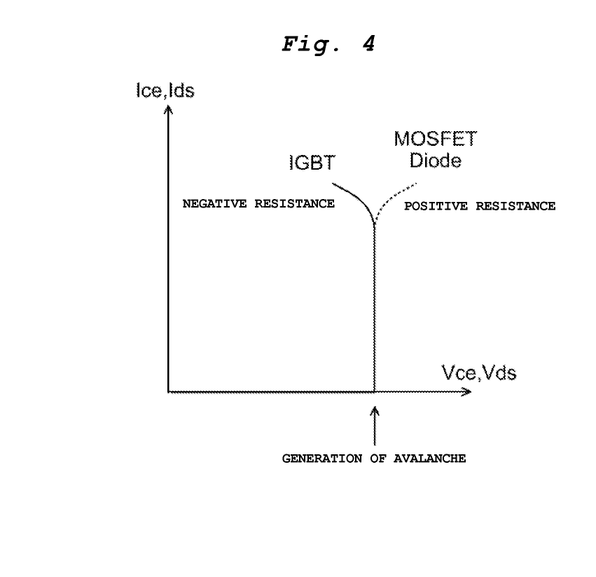

FIG. 4 illustrates a summary of the results of Reference Examples 1 and 2. FIG. 4 is a diagram illustrating the voltage versus current characteristics of the semiconductor device according to Reference Examples 1 and 2.

Here, the abscissa represents the collector—emitter voltage Vce or the drain—source voltage Vds. The ordinate represents the collector—emitter current Ice or the drain—source current Ids.

For a MOSFET (or diode), in an avalanche, as the Vds increases, the Ids increases. On the other hand, for an IGBT, in an avalanche, as the Vce decreases, the Ice decreases.

With respect to this, the operation of the semiconductor device 1 according to the first embodiment will be explained.

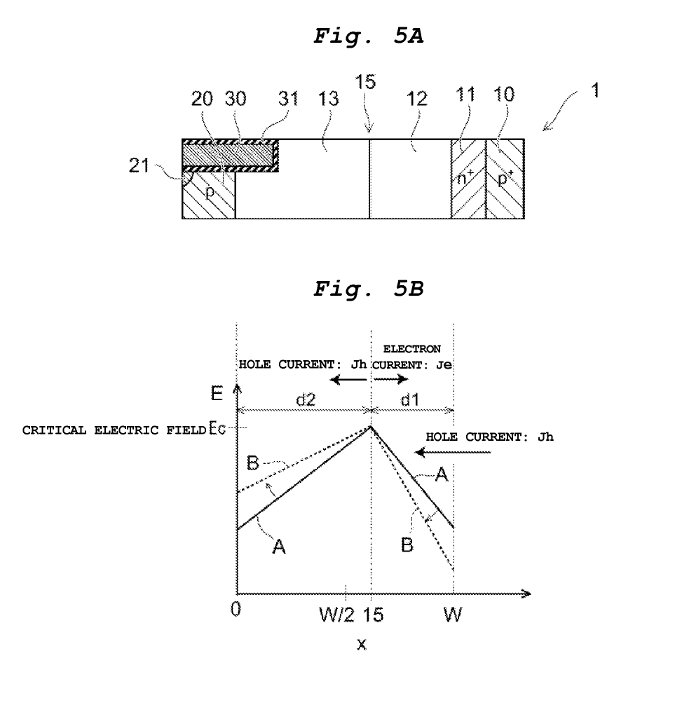

FIGS. 5A and 5B include diagrams illustrating the electric field in the super-junction structure of the semiconductor device according to the first embodiment of the present disclosure. FIG. 5A is a schematic cross-sectional view of the semiconductor device. FIG. 5B is a diagram illustrating the relationship between the position in the super-junction structure of the semiconductor device and the electric field.

In FIG. 5B, the abscissa represents the position from the boundary between the base layer 20 and the semiconductor layer 13 and the boundary between the semiconductor layer 12 and the buffer layer 11. The boundary between the base layer 20 and the semiconductor layer 13 corresponds to the position 0 in FIG. 5B, and the boundary between the semiconductor layer 12 and the buffer layer 11 corresponds to the position W in FIG. 5B. In FIG. 5B, the ordinate represents the electric field.

Line A is a line representing the relationship between the position and electric field in the semiconductor layers 12, 13 right after an avalanche after a voltage is applied between the emitter and the collector. Also, line B is a line representing the relationship between the position and electric field in the semiconductor layers 12, 13 after lapse of a prescribed time after the avalanche. Here, a positive potential is applied on the collector side, and a negative or ground potential is applied on the emitter side.

When an avalanche breakdown takes place, an electron current is generated inside the semiconductor layers 12, 13. In addition, holes are injected from the collector layer 10 into the semiconductor layer 12 corresponding to the generation of the electron current.

Here, the semiconductor layer 12 is in the n-rich state (relatively high concentration of n-type dopants), and the semiconductor layer 12 has holes injected from the collector layer 10 into it. Consequently, the behavior of the line A and line B in the semiconductor layer 12 displays the same tendency as that of the semiconductor device 200. That is, line B is located on the lower side of line A.

On the other hand, the semiconductor layer 13 is in the p-rich state (relatively low concentration of n-type dopants), and the semiconductor layer 13 has the holes injected from the semiconductor layer 12 into it. Consequently, the behavior of line A and line B in the semiconductor layer 13 has a tendency opposite that of the semiconductor layer 12. This is because the carriers contained in the p-rich semiconductor are mostly holes, and the carriers contained in the n-rich semiconductor are mostly electrons. That is, line B is positioned on the upper side of line A.

In the semiconductor device 1, the length d1 is shorter than the length d2. Consequently, the interface 15 is located between W/2 and W.

In the semiconductor device 1, the area defined by the abscissa between position 0 and position W, the ordinate between position 0 and position W, and line B in FIG. 5B is larger than the area defined by the abscissa between position 0 and position W, the ordinate between position 0 and position W, and line A in FIG. 5B. As explained above, such an area corresponds to the voltage applied on the semiconductor layers 12, 13. That is, for the semiconductor device 1, in the avalanche, a positive resistance characteristic feature is displayed, with the voltage increasing while the avalanche current increases.

As a result, in the semiconductor device 1, a negative resistance generally does not take place during the avalanche. Consequently, during the avalanche, localized current concentrations do not form inside the element. As a result, for the semiconductor device 1, the tolerance to breakdown increases. In addition, the avalanche point in the semiconductor device 1 is at the position of the interface 15 with the highest electric field.

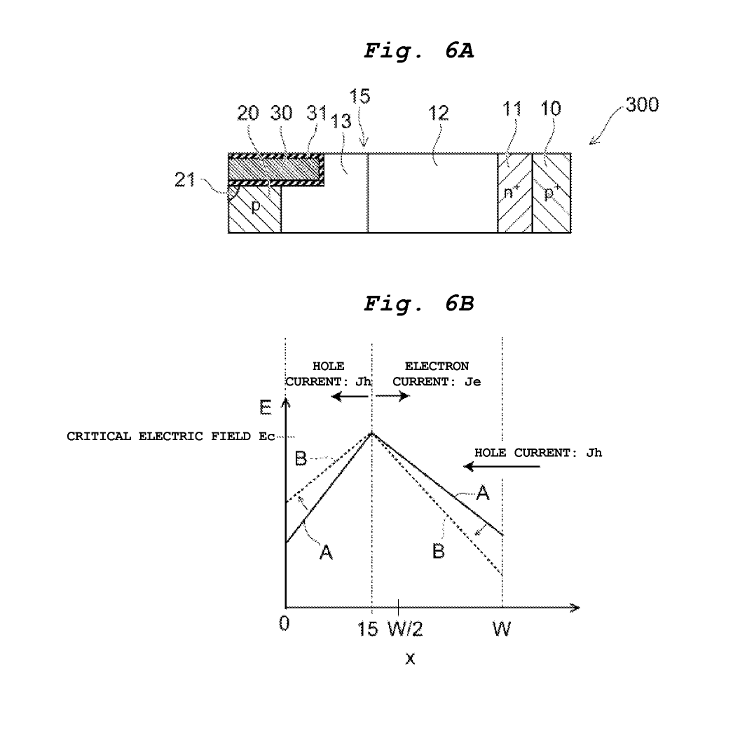

FIGS. 6A and 6B are diagrams illustrating the electric field in the super-junction structure of the semiconductor device according to Reference Example 3. FIG. 6A is a schematic cross-sectional view of the semiconductor device. FIG. 6B is a diagram illustrating the relationship between the position in the super-junction structure of the semiconductor device and the electric field.

In the semiconductor device 300 according to Reference Example 3, the interface 15 is located between position 0 and position W/2. In this case, the area defined by the abscissa between position 0 and position W, the ordinate between position 0 and position W, and line B in FIG. 6B is smaller than the area defined by the area defined by the abscissa between position 0 and position W, the ordinate between position 0 and position W, and line A in FIG. 6B. That is, even when the semiconductor device has semiconductor layers 12, 13, when the interface 15 is positioned between 0 and W/2, a negative resistance takes place with the voltage decreasing while the avalanche current increases.

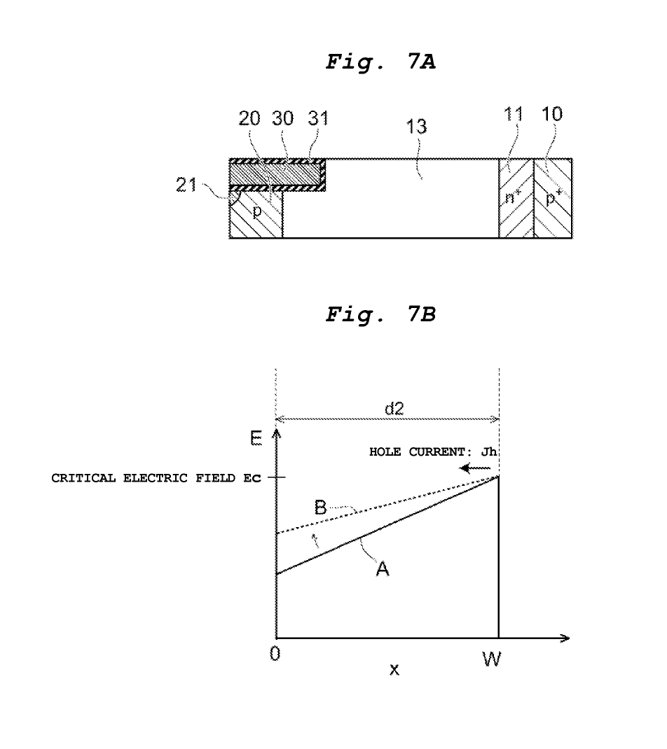

FIGS. 7A and 7B include diagrams illustrating the electric field in the super-junction structure of the semiconductor device according to the first embodiment. FIG. 7A is a schematic cross-sectional view of the semiconductor device. FIG. 7B is a diagram illustrating the relationship between the position in the super-junction structure of the semiconductor device and the electric field.

In a modified example of the first embodiment, d1 is set at 0, and the super-junction structure includes only the semiconductor layer 13.

In this case, too, the area defined by the abscissa between position 0 and position W, the ordinate between position 0 and position W, and line B in FIG. 7B is larger than the area defined by the abscissa between position 0 and position W, the ordinate between position 0 and position W, and line A in FIG. 7B. Consequently, even in the modified example of the first embodiment, during avalanche, a positive resistance characteristic feature is displayed, with the voltage increasing while the avalanche current increases. That is, it is preferred that that interface 15 between semiconductor layer 12 and semiconductor layer 13 be located between W/2 and W. More specifically, the interface 15 is located at the position between W/2 and W. In addition, in the modified example of the first embodiment, the avalanche point is at the position of the interface between the semiconductor layer 13 and the buffer layer 11.

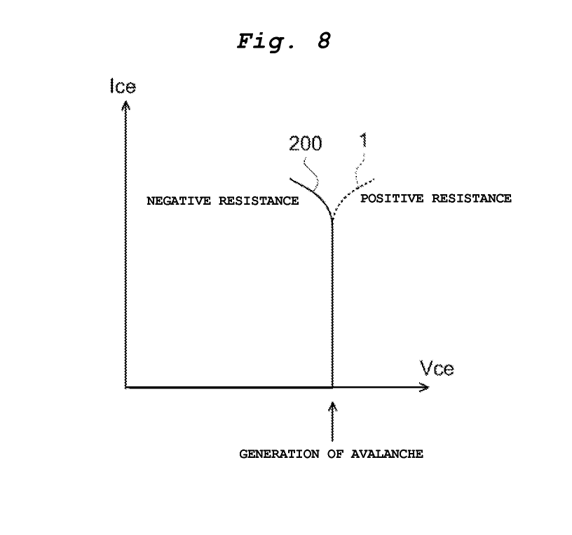

The results can be summarized in FIG. 8.

FIG. 8 is a diagram illustrating the voltage-current characteristics of the semiconductor device according to Reference Examples 1 and 2.

For the semiconductor device 200, in an avalanche, while Vce decreases, Ice increases. On the contrary, for the semiconductor device 100, in an avalanche, while Vce increases, Ice increases.

As a result, according to the first embodiment, a 2-step super-junction structure is provided as the drift layer of the IGBT element. For example, on the MOS side of the outer surface of the element, a p-rich super-junction structure is formed, and, on the collector side of the back surface of the element, an n-rich super-junction structure is formed. In the first embodiment, the avalanche point is set on the collector side at a position of less than half the thickness of the drift layer.

As a result, according to the first embodiment, even when holes are injected from the collector side in an avalanche, due to presence of the p-rich semiconductor layer 13, the slope of the electric field distribution becomes less severe. Therefore, according to the first embodiment, a positive resistance characteristic feature is displayed, with the voltage increasing while the avalanche current increases. As a result, according to the first embodiment, a negative resistance is unlikely to take place in the element, and the tolerance of the element to breakdown increases.

### Second Embodiment

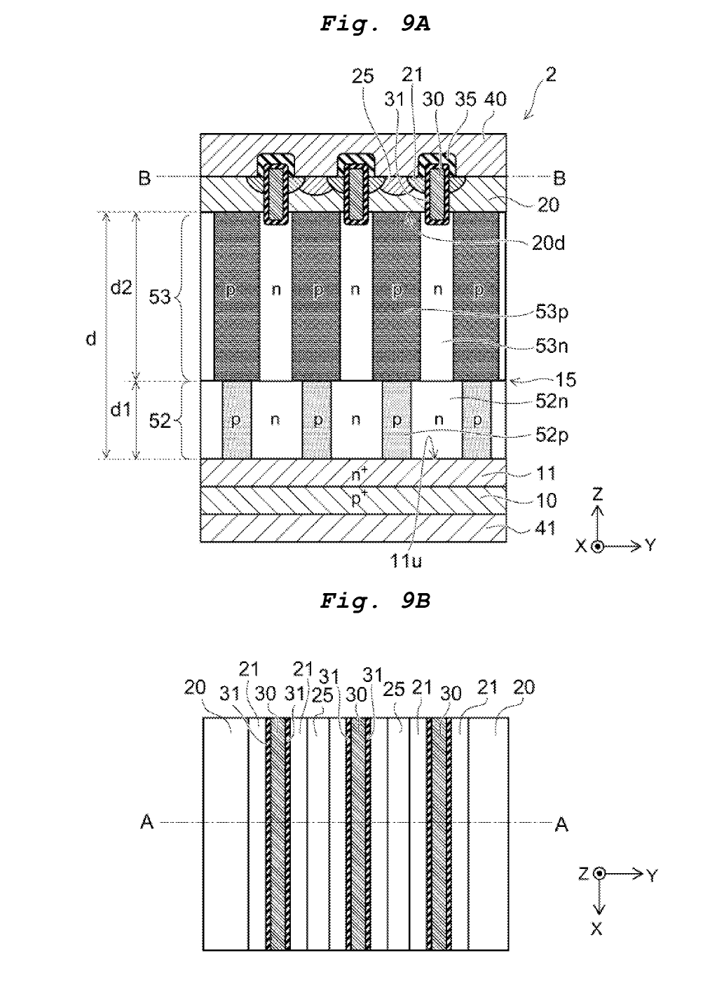

FIGS. 9A and 9B include schematic diagrams of the semiconductor device according to the second embodiment. FIG. 9A is a schematic cross-sectional view. FIG. 9B is a schematic plane view.

The structure of semiconductor device 2 according to the second embodiment is identical to that of the semiconductor device 1 in the first embodiment, except for the super-junction structure. In the following, the super-junction structure of the semiconductor device 2 will be explained.

The semiconductor layer 52 of the semiconductor device 2 has a super-junction structure. In the semiconductor layer 52, the p type semiconductor layer regions 52p and the n type semiconductor layer regions 52n are arranged alternately in the first direction (Y-direction) perpendicular to the laminating direction (Z-direction) of the collector layer 10 and the buffer layer 11. The shape of the semiconductor layer regions 52p and the semiconductor layer regions 52n are the pillar shape on the cross-section shown as an example in FIG. 9A. The semiconductor layer regions 52p and the semiconductor layer regions 52n also extend in X-direction. The semiconductor layer regions 52p and the semiconductor layer regions 52n are jointed to the buffer layer 11. The semiconductor layer regions 52p and the semiconductor layer regions 52n have the same impurity concentration.

The semiconductor layer 53 of the semiconductor device 2 has a super-junction structure. In the semiconductor layer 53, the p type semiconductor layer regions 53p and the n type semiconductor layer regions 53n are arranged alternately in the first direction (Y-direction) with respect to the laminating direction (Z-direction). The semiconductor layer regions 52p are connected to the semiconductor layer regions 53p. The semiconductor layer regions 52n are connected to the semiconductor layer regions 53n. The shape of the semiconductor layer regions 53p and the shape of the semiconductor layer regions 53n are of the pillar shape on the cross-section shown as an example in FIG. 9A. The semiconductor layer regions 53p and the semiconductor layer regions 53n extend in X-direction. The semiconductor layer regions 53p and semiconductor layer regions 53n have the same impurity concentration level.

The principal ingredient of the semiconductor layers 52, 53 is, e.g., silicon (Si). The semiconductor layers 52, 53 may be either epitaxial layers or ion implanting layers.

In the semiconductor device 2, the width in the Y-direction of the semiconductor layer regions 52n is wider than the width in the Y-direction of the semiconductor layer regions 52p. Consequently, the semiconductor layer 52 is an n-rich semiconductor layer. The width of the semiconductor layer regions 53p in the Y-direction is wider than the width of the semiconductor layer regions 53n in Y-direction. Consequently, the semiconductor layer 53 is a p-rich semiconductor layer. Here, the length d1 between the upper end 11u of the buffer layer 11 and the interface 15 between the semiconductor layer 52 and the semiconductor layer 53 is shorter than the length d2 between the interface 15 and the lower end 20d of the base layer 20.

Consequently, the operation of the semiconductor device 2 is substantially the same as that of the semiconductor device 1. The semiconductor device 2 displays the same effect as that of the semiconductor device 1.

In the above, embodiments have been explained with reference to examples. However, the embodiments are not limited to the examples. That is, modifications of the examples by appropriate changes in the design by the specialists are included in the range of the embodiments, as long as the characteristic features of the embodiments are equipped. The configuration, materials, conditions, sizes, etc. of the various elements in the examples are not limited to the examples, and they may be changed appropriately.

The various elements in these embodiments may be combined appropriately as long as they are technically allowed. As long as the combinations have the characteristic features of the embodiments, they are also included in the range of the embodiments. In addition, within the range of the idea of the embodiments, the specialists can make various types of changes and corrections, and such changes and corrections are included in the range of the embodiments as well.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor layer of a first conductivity type;
a second semiconductor layer of a second conductivity type, disposed on the first semiconductor layer;
a third semiconductor layer disposed on the second semiconductor layer, the third semiconductor layer comprising first semiconductor regions of the first conductivity type and second semiconductor regions of the second conductivity type, the first semiconductor regions alternating with the second semiconductor regions in a first direction;
a fourth semiconductor layer disposed on the third semiconductor layer, the fourth semiconductor layer comprising third semiconductor regions of the first conductivity type and fourth semiconductor regions of the second conductivity type, the third semiconductor regions alternating with the fourth semiconductor regions in the first direction;
a fifth semiconductor layer of the first conductivity type disposed on the fourth semiconductor layer; a sixth semiconductor layer of the second conductivity type disposed on the fifth semiconductor layer; and
a gate electrode disposed on a gate insulation layer that is in contact with the fourth semiconductor layer, the fifth semiconductor layer, and the sixth semiconductor layer;
wherein the third semiconductor layer has a concentration of second type conductivity dopants that is greater than the fourth semiconductor layer and is thinner than the fourth semiconductor layer, and the second semiconductor regions of the third semiconductor layer contact respective fourth semiconductor conductor regions of the fourth semiconductor layer.

2. The semiconductor device of claim 1, wherein the first semiconductor regions and the second semiconductor regions each have a same width along the first direction.

3. The semiconductor device of claim 1, wherein the third semiconductor regions and the fourth semiconductor regions each have a same width along the first direction.

4. The semiconductor device of claim 3, wherein the first semiconductor regions and the second semiconductor regions each have a same width along the first direction.

5. The semiconductor device of claim 1, wherein the first semiconductor regions have a dopant concentration that is greater than the second semiconductor regions.

6. The semiconductor device of claim 1, wherein the third semiconductor regions have a dopant concentration greater than the fourth semiconductor regions.

7. The semiconductor device of claim 1, wherein the gate electrode has a trench gate structure.

8. The semiconductor device of claim 1, wherein the gate electrode comprises polysilicon.

9. The semiconductor device of claim 1, further comprising:
an emitter electrode disposed above the sixth semiconductor layer; and
a collector electrode disposed below the first semiconductor layer.

10. The semiconductor device of claim 1, further comprising a hole-extracted layer disposed on the fifth semiconductor layer and in contract with the sixth semiconductor layer.

11. The semiconductor device of claim 1, wherein the third semiconductor layer and the fourth semiconductor layer have a super-junction structure.

12. A semiconductor device, comprising:
a first semiconductor layer of a first conductivity type;
a second semiconductor layer of a second conductivity type disposed on the first semiconductor layer;
a third semiconductor layer disposed on the second semiconductor layer, the third semiconductor layer with a structure wherein first semiconductor regions of the first conductivity type and second semiconductor regions of the second conductivity type are arranged alternately in a first direction perpendicular to a stacking direction of the first semiconductor layer and the second semiconductor layer;
a fourth semiconductor layer disposed on the third semiconductor layer, the fourth semiconductor layer with a structure wherein third semiconductor regions of the first conductivity type and fourth semiconductor regions of the second conductivity type are arranged alternately in the first direction;
a fifth semiconductor layer of the first conductivity type disposed on the fourth semiconductor layer;
a sixth semiconductor layer of the second conductivity type disposed on the fifth semiconductor layer;
a first electrode connected via an insulating film to the sixth semiconductor layer, the fifth semiconductor layer, and a fourth semiconductor region;
a second electrode connected to the sixth semiconductor layer; and
a third electrode connected to the first semiconductor layer; wherein
a concentration of a first dopant in the second semiconductor regions is higher than the concentration of a second dopant in the first semiconductor regions;
the concentration of the second dopant in the third semiconductor regions is higher than the concentration of the first dopant in the fourth semiconductor regions, and
a first length between a upper end surface the second semiconductor layer and an interface between the third semiconductor layer and the fourth semiconductor layer is less than a second length between the interface and a lower surface of the fifth semiconductor layer.

13. The semiconductor device of claim 12, wherein
the first semiconductor regions are connected to the third semiconductor regions, and
the second semiconductor regions are connected to the fourth semiconductor regions.

14. The semiconductor device of claim 13, wherein
the first semiconductor regions and the second semiconductor regions are contacting the second semiconductor layer.

15. The semiconductor device of claim 12, wherein a width of each second semiconductor region along the first direction is greater than a width of each first semiconductor region along the first direction;
a width of the third semiconductor regions along the first direction is greater than a width of the fourth semiconductor regions along the first direction,

16. A semiconductor device, comprising:
a first semiconductor layer of a first conductivity type;
a second semiconductor layer of a second conductivity type disposed on the first semiconductor layer;
a third semiconductor layer disposed on the second semiconductor layer, the third semiconductor layer has a structure wherein first semiconductor regions of the first conductivity type and second semiconductor regions of the second conductivity type are arranged alternately in a first direction perpendicular to a stacking direction of the first semiconductor layer and the second semiconductor layer;
a fourth semiconductor layer disposed on the third semiconductor layer, the fourth semiconductor layer has a structure wherein third semiconductor regions of the first conductivity type and fourth semiconductor regions of the second conductivity type are arranged alternately in the first direction;
a fifth semiconductor layer of the first conductivity type disposed on the fourth semiconductor layer;
a sixth semiconductor layer of the second conductivity type disposed on the fifth semiconductor layer;
a first electrode connected via an insulating film to the sixth semiconductor layer, the fifth semiconductor layer, and a fourth semiconductor region;
a second electrode connected to the sixth semiconductor layer; and
a third electrode connected to the first semiconductor layer; wherein,
a width of each second semiconductor region in the first direction is greater than a width of each first semiconductor region along the first direction;
a width of each third semiconductor region along the first direction is greater than a width of each fourth semiconductor region along the first direction; and
a first length between an upper surface of the second semiconductor layer and an interface between the third semiconductor layer and the fourth semiconductor layer is less than a second length between the interface and a lower surface of the fifth semiconductor layer.

17. The semiconductor device of claim 16, wherein
the first semiconductor regions are connected to the third semiconductor regions; and
the second semiconductor regions are connected to the fourth semiconductor regions.

18. The semiconductor device of claim 17, wherein,
the first semiconductor regions and the second semiconductor regions are connected to the second semiconductor layer.

19. The semiconductor device of claim 18, wherein,
a concentration of a first dopant in the second semiconductor regions is higher than the concentration of a second dopant in the first semiconductor regions; and
the concentration of the second dopant in the third semiconductor regions is higher than the concentration of the first dopant in the fourth semiconductor regions.

20. The semiconductor device of claim 19, wherein the third semiconductor layer and the fourth semiconductor layer form a super-junction structure.
